(19) United States
(12) Patent Application Publication
(10) Pub. No.: US 2008/0003768 A1
(43) Pub. Date: Jan. 3, 2008

(54) CAPACITOR OF A MEMORY DEVICE AND METHOD FOR FORMING THE SAME

(75) Inventor: Jae Min Oh, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/618,628

(22) Filed: Dec. 29, 2006

(30) Foreign Application Priority Data
Jun. 29, 2006 (KR) 10-2006-0059917

(51) Int. Cl. H01L 21/20

(52) U.S. Cl. 438/399

(57) ABSTRACT

A capacitor of a memory device is formed on a semiconductor substrate having transistors thereon. A mold layer having holes defined therein is formed on the semiconductor substrate. A catalytic metal layer is formed proximate to a bottom boundary of each hole. Reaction gas is fed to the catalytic metal layer to form carbon nanotubes via a catalytic reaction of the reaction gas by the catalytic metal layer. After forming a lower electrode layer proximate to the bottom boundary and sidewall of each hole and over the carbon nanotubes, a dielectric layer is deposited over the lower electrode layer. Upper electrodes are formed on the dielectric layer to form capacitors electrically connected to the transistors.

### CROSS-REFERENCES TO RELATED APPLICATIONS

The present application claims priority to Korean patent application number 10-2006-0059917, filed on Jun. 29, 2006, which is incorporated herein by reference in its entirety.

### BACKGROUND OF THE INVENTION

The present invention relates to semiconductor devices, and more particularly, to capacitors of memory devices and a method for forming the same.

Semiconductor devices exhibit an increasing need for fine patterns in a limited area. In dynamic random access memory (DRAM) devices, a single transistor and a single capacitor constitute a single memory cell. The DRAM device is designed such that the capacitor achieves maximum capacitance in a limited area. In a DRAM device of 80 nanometers or less, achieving the desired capacitance of a capacitor may be problematic.

In order to increase the capacitance of a capacitor in a semiconductor device, a dielectric layer is formed with a dielectric material having a high dielectric constant. An effective surface area of the dielectric layer may be increased by increasing an effective surface area of a lower electrode of the capacitor (e.g., in a cylindrical capacitor).

The greater the height of a capacitor, the greater the height of a metal contact (e.g., an M1C style metal contact) that is connected to metal 1 wirings. Thus, margins of photographing and etching processes are reduced rapidly and many defects may occur during formation of the capacitor due to the increased height of the capacitor. These problems, consequently, result in a reduction in processing yield.

When using a dielectric material having a high dielectric constant, an electrode structure may be changed from a general silicon-insulator-silicon (SIS) structure to a metal-insulator-metal (MIM) structure, so as to achieve a desired capacitance. However, dielectric characteristics of the dielectric layer or leakage current characteristics of a capacitor may be changed easily due to a thermal budget attendant on a subsequent process. To reduce a leakage current, a composite dielectric layer may be formed by adding a dielectric material having a low dielectric constant. However, the limit to which the capacitance of a capacitor may be increased is lowered.

### SUMMARY OF THE INVENTION

In accordance with one aspect of the present invention, a method for forming capacitors of a memory device includes forming a mold layer over a semiconductor substrate. The mold layer is formed with holes. A catalytic metal layer is formed proximate to a bottom boundary of each hole. Carbon nanotubes are formed over the catalytic metal layer. A dielectric layer is deposited over the carbon nanotubes. Upper electrodes are formed over the dielectric layer to form capacitors.

The carbon nanotubes may be formed to be substantially orthogonal to the catalytic metal layer.

Prior to the formation of the mold layer, the method may further comprise: forming an insulating layer over the semiconductor substrate to cover the transistors; and forming connection contacts extending below the insulating layer to electrically connect the semiconductor substrate to the lower electrode layer.

The catalytic metal layer may be formed of a nickel (Ni) layer, an iron (Fe) layer, or both.

The carbon nanotubes may be formed by a catalytic reaction of a reaction gas with the catalytic metal layer, The reaction gas may include hydrocarbon gas comprising acetylene gas (C₂H₄), methane gas (CH₄), or both.

The dielectric layer may be formed of an aluminum oxide layer, a hafnium oxide layer, a zirconium oxide layer, or a combination thereof, deposited by an atomic layer deposition (ALD) process.

In accordance with another aspect of the present invention, a capacitor of a memory device includes transistors. The capacitor comprises a catalytic metal layer formed on a semiconductor substrate. Carbon nanotubes are formed over the catalytic metal layer such that the carbon nanotubes are substantially orthogonal to the catalytic metal layer. A dielectric layer is formed over the carbon nanotubes and an upper electrode is formed over the dielectric layer.

The carbon nanotubes may be formed directly on the catalytic metal layer. The capacitor may further comprise a mold layer formed on the semiconductor substrate. The mold layer defines at least one hole. A lower electrode layer is formed proximate to a bottom boundary and a sidewall of each hole and over the carbon nanotubes. The capacitor may further comprise a lower electrode layer that forms a cylindrical sidewall surrounding a periphery of the carbon nanotubes while covering the carbon nanotubes and the catalytic metal layer.

The capacitor may further comprise an insulating layer formed over the semiconductor substrate to cover the transistors and a connection contact penetrating through the insulating layer to electrically connect the semiconductor substrate to the lower electrode layer.

### BRIEF DESCRIPTION OF THE DRAWINGS

FIGS. 1 to 5 are sectional views schematically illustrating a capacitor of a memory device and a method for forming the same according to an embodiment of the present invention; and

FIG. 6 is a schematic plan view of capacitors according to an embodiment of the present invention.

### DESCRIPTION OF THE SPECIFIC EMBODIMENTS

In a preferred embodiment of the present invention, a capacitor is disclosed in which a dielectric layer having a high dielectric constant is preferably formed by an atomic layer deposition (ALD) process and an effective surface area of the dielectric layer is increased.

The capacitor may be formed with a dielectric material having a high dielectric constant. For example, the dielectric material may be aluminum oxide (Al₂O₃) having a dielectric constant of approximately 9, hafnium oxide (HfO₂) or zirconium oxide (ZrO₂) having a dielectric constant of approximately 50.

A capacitor of a semiconductor device is formed using a concave mold or template. A barrier metal layer is formed over the mold or template to substantially prevent diffusion of a conductive layer or a metal layer used to form a lower electrode. Subsequently, a catalytic metal layer or a seed layer for use in the formation of carbon nanotubes is deposited over the barrier metal layer. After the carbon nanotubes are formed, a lower electrode layer, a dielectric layer, and an upper electrode layer are sequentially deposited over the nanotubes so as to achieve a significant increase in an effective surface area of the capacitor. With the resulting effective surface area of the capacitor, a high capacitance is achieved.

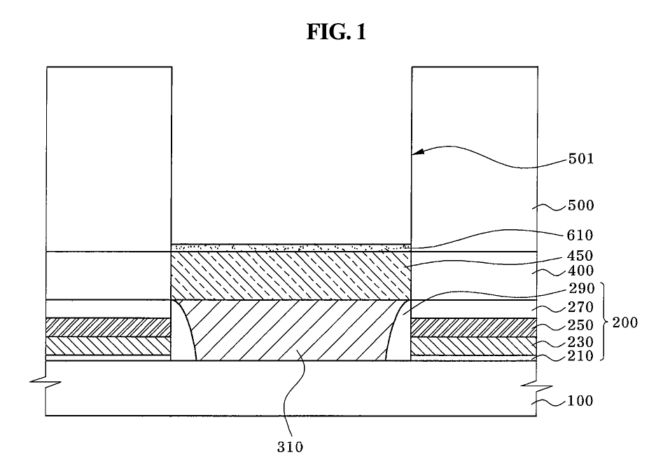

Referring to FIG. 1, a device-isolating structure (not shown) is formed on a semiconductor substrate 100 by a shallow trench isolation (STI) technique to define active regions on the semiconductor substrate 100. Gate stacks 200 are formed on the active regions. Each of the gate stacks 200 includes a gate oxide layer 210, a conductive poly-silicon layer 230, a tungsten-silicide (WSiₓ) layer 250, a silicon nitride capping layer 270, and insulating spacers 290. After completing formation of the gate stacks 200, an ion injection process for forming sources and drains is performed to form transistors.

It is appreciated that the above described transistors are used in the formation of DRAM devices in which a single transistor and a single capacitor constitute a memory cell unit. The invention, however, may be implemented for other types of semiconductor devices.

A lower insulating layer (not shown) is deposited to fill gaps between the gate stacks 200. Contact pads 310, which include a conductive material layer (e.g., a conductive poly-silicon layer) are formed to penetrate through the lower insulating layer. An insulating interlayer 400 is formed to cover the contact pads 310. Connection contacts 450 are formed to penetrate through the insulating interlayer 400 so as to be aligned with the contact pads 310. The connection contacts 450 become connected to lower electrodes of capacitors and include a conductive material layer (e.g., a conductive poly-silicon layer). Although not shown, it is understood that a bit line forming process may be additionally performed such that the connection contacts 450 are aligned with the contact pads 310 through bit lines.

A mold layer 500 is formed on the insulating interlayer 400 to impart a three-dimensional structure, such as a cylindrical structure, to lower electrodes of the capacitors. Holes 501 are formed through the mold layer 500 to be aligned with the connection contacts 450. It is understood that the mold layer 500 may be a sacrificial layer to be removed in a subsequent process, or an insulating layer for isolating and insulating the capacitors. Accordingly, the mold layer 500 may be formed of a silicon oxide layer, such as a PE-TEOS oxide layer. It is understood that the mold layer 500 is a structure for causing lower electrodes of the capacitors to have a cylindrical shape.

A seed layer or catalytic metal layer 610 is formed on the connection contacts 450 to form a bottom boundary of each hole 501. The catalytic metal layer 610 can be formed of a transition metal layer that is usable as a reaction catalyst in a reaction for forming carbon nanotubes. For example, the catalytic metal layer 610 may be formed by depositing a nickel (Ni) layer. Alternatively, instead of the nickel layer, an iron (Fe) layer may be deposited to form the catalytic metal layer 610. Alternatively, the catalytic metal layer 610 may be formed of an alloy layer obtained by combining iron, nickel, cobalt (Co), or titanium (Ti). For example, the catalytic metal layer 610 may be formed of an iron-nickel binary-system alloy layer, an iron-nickel-cobalt ternary-system alloy layer, an iron-nickel-cobalt-titanium quarternary-system alloy layer, or an iron-nickel-titanium ternary-system alloy layer.

The catalytic metal layer 610 is selectively deposited on the connection contacts 450 to form a bottom boundary of each hole 501 so as not to be extended to a sidewall of each hole 501. Accordingly, to prevent the catalytic metal layer 610 from being deposited on the sidewall of each hole 501, the catalytic metal layer 610 may be deposited by a method having a poor step coverage property (e.g., a sputtering method). Alternatively, to restrict the formation range of the catalytic metal layer 610 onto the connection contacts 450 at the bottom boundary of each hole 501, the mold layer 500 is formed after depositing and patterning the catalytic metal layer 610 on the connection contacts 450.

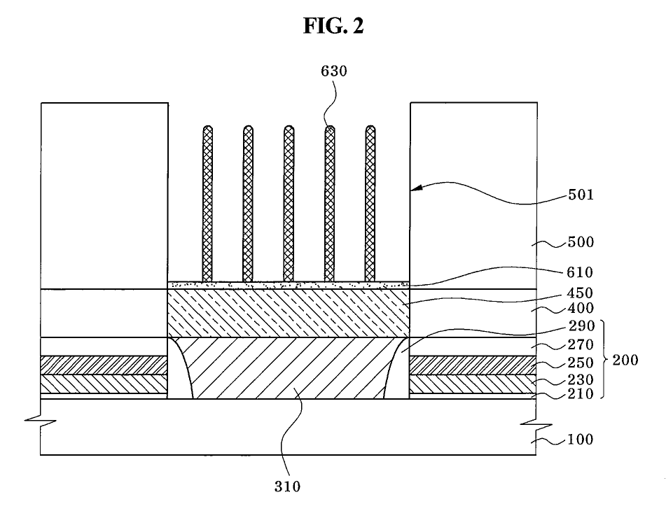

Referring to FIG. 2, reaction gas (e.g., hydrocarbon gas) is fed onto the catalytic metal layer 610 such that carbon nanotubes 630 are formed on the catalytic metal layer 610 by a catalytic reaction of the hydrocarbon gas by the catalytic metal layer 610. The carbon nanotubes 630 are formed substantially orthogonal to the catalytic metal layer 610. Examples of the hydrocarbon gas may include acetylene (C₂H₂) gas, ethylene (C₂H₄) gas, propylene gas, propane gas, and methane gas (CH₄), which have approximately 20 or less carbon units and are capable of providing carbon dimers. Preferably, acetylene gas, which has a relatively high degree of unsaturation by triple bonds, is used.

In addition to the hydrocarbon gas, inert gas, such as hydrogen (H₂) gas or argon (Ar) gas, may be used as a carrier gas. Diluted hydride gas may be fed along with the reaction gas. To facilitate the reaction for forming the carbon nanotubes, a processing chamber is maintained at a pressure of approximately 200 torr and a temperature of 300° C.-400° C.

The hydrocarbon gas produces carbon units by thermal decomposition and the produced carbon units are adsorbed to a surface of the catalytic metal layer 610 to be diffused in the surface of and into the catalytic metal layer 610. The carbon units are converted into carbon dimers (C═C) in the surface of or in the catalytic metal layer 610. If the carbon dimers in the catalytic metal layer 610 reach a supersaturated state, the carbon dimers interact with one another in the surface of the catalytic metal layer 610 to create a repetitive honeycomb structure having annular hexagons when viewed from above.

If the carbon dimers are continuously fed into the catalytic metal layer 610, the carbon nanotubes 630 are synthesized and formed on the catalytic metal layer 610 with a honeycomb structure. Specifically, the carbon nanotubes 630 are formed to be substantially orthogonal to the catalytic metal layer 610. The reaction gas may include ammonia gas (NH₃) in addition to the hydrocarbon gas. It is understood that the ammonia gas acts to facilitate the substantially orthogonal orientation of the carbon nanotubes 630.

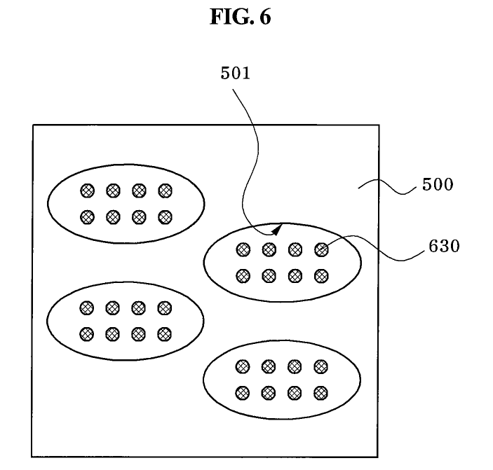

As shown in FIG. 6, the plurality of carbon nanotubes 630 are formed in each hole 501 to be substantially orthogonal to the catalytic metal layer 610. It is understood that the carbon nanotubes 630 may have a diameter from several nanometers to dozens of nanometers and a length from several tens to a hundred times the diameter.

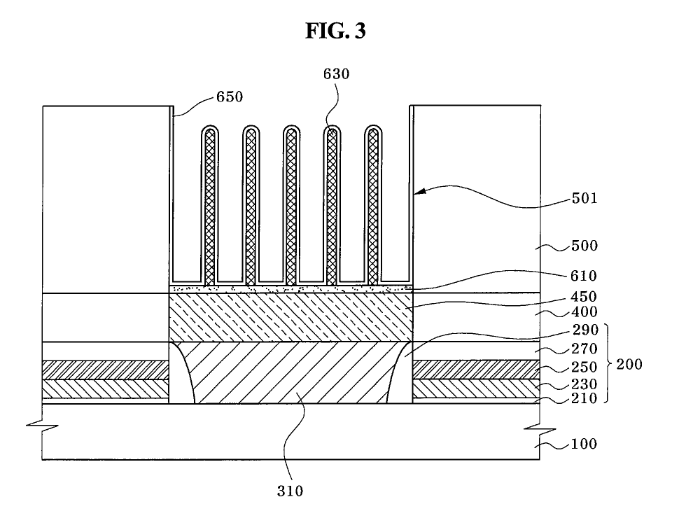

Referring to FIG. 3, a lower electrode layer 650 is formed proximate to the bottom boundary and the sidewall of each hole 501 and covering the carbon nanotubes 630. For example, after forming a conductive layer along a profile of each hole 501, a lower electrode is separated by a removing process, such as an etch back or chemical/mechanical polishing (CMP) process, to produce a substantially cylindrical single lower electrode for each connection contact 450. In other words, the lower electrode layer 650 is formed to produce a cylindrical sidewall surrounding the periphery of the carbon nanotubes 630 while covering the carbon nanotubes 630 and the catalytic metal layer 610.

The above described lower electrode layer 650 may be deposited by an ALD process to realize a good step coverage property. The lower electrode layer 650 may be made of various conductive materials, and more particularly, may be formed of a titanium nitride (TiN) layer. Alternatively, the lower electrode layer 650 may be formed of a titanium/titanium nitride layer, or may be formed of tungsten nitride (WN), tantalum nitride (TaN), platinum (Pt), ruthenium (Ru), or the like.

As occasion demands, the lower electrode layer 650 may be omitted. Since the substantially orthogonally oriented carbon nanotubes 630 may have a vertical conductive path, i.e., a lengthwise conductive path, both the carbon nanotubes 630 and the lower catalytic metal layer 610 may constitute the lower electrode of the capacitor.

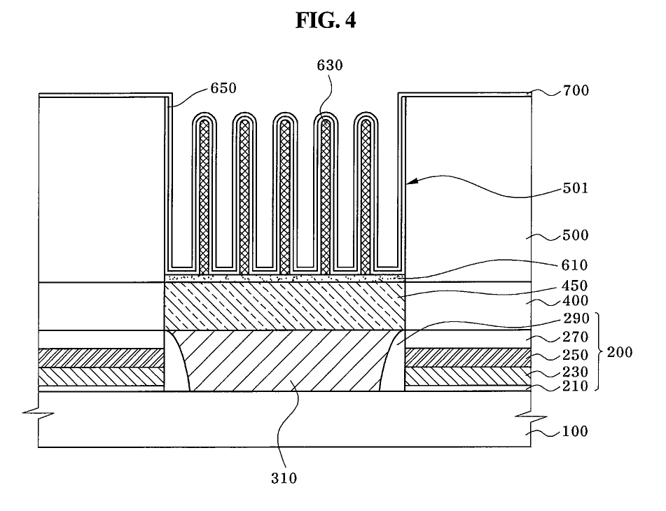

Referring to FIG. 4, a dielectric layer 700 is formed on the lower electrode layer 650 to follow a three-dimensional profile defined by each hole 501 and the carbon nanotubes 630. Since the carbon nanotubes 630 are formed on the bottom boundary of each hole 501 in a substantially orthogonal direction from the bottom boundary, an effective surface area of the dielectric layer 700 is increased by the carbon nanotubes 630.

The dielectric layer 700 is made of a dielectric material having a high dielectric constant. For example, the dielectric layer 700 may be formed of a zirconium oxide (ZrO₂) layer. The zirconium oxide layer is deposited along a three-dimensional profile by an ALD process with a good step coverage property. A zirconium source for use in the ALD process may include precursors formed by bonding organic ligands to zirconium metal atoms, such as Zr[N(CH₃)]₄, Zr[N(CH₂CH₃)]₄, Zr[N(CH₃) (CH₂CH₃)]₄, Zr[N(CH₃)₂(CH₂CH₃)₂]₄, or the like.

The above mentioned precursors may be thermally decomposed at a considerably high temperature, for example, at a temperature higher than approximately 320° C. When the zirconium source is thermally decomposed, a chemical vapor deposition (CVD) process, rather than an ALD process, may occur. To prevent the occurrence of the CVD process, it is preferable that the deposition temperature be lower than the above mentioned temperature (e.g., in a range of approximately 250° C. to 320° C.). However, when the zirconium oxide is deposited at the above low temperature by an ALD process, a relatively low crystallization is realized, which makes it difficult to obtain a desired high dielectric constant.

Accordingly, in the embodiment of the present invention, an additional heat treatment or crystallizing treatment is performed to improve the crystallization of the dielectric layer 700 including the zirconium oxide layer.

Although the dielectric layer 700 may be formed of a single zirconium oxide layer, it may also be formed of a composite layer, such as a triple layer including an aluminum oxide layer (Al₂O₃) and a zirconium oxide layer (ZrO₂), etc., to achieve a greater capacitance and improve leakage current characteristics. The Al₂O₃/ZrO₂ laminated structure is effective to improve leakage current characteristics. In view of mass production, it is preferable to perform an ALD process of depositing zirconium oxide (ZrO₂), aluminum oxide (Al₂O₃), and zirconium oxide (ZrO₂) in sequence by an in-situ course within the same processing chamber.

In the above described ALD process, an aluminum source may include Al(CH₃)₃. An oxygen source required for an ALD deposition of zirconium oxide and ALD deposition of aluminum oxide may include ozone gas, water vapor (H₂O), or the like.

In addition to the above described aluminum oxide layer or zirconium oxide layer, the dielectric layer 700 may be formed to have a single layer or composite layer structure including a hafnium oxide layer (HfO₂). It remains preferable to employ an ALD process for achieving an improved step coverage property.

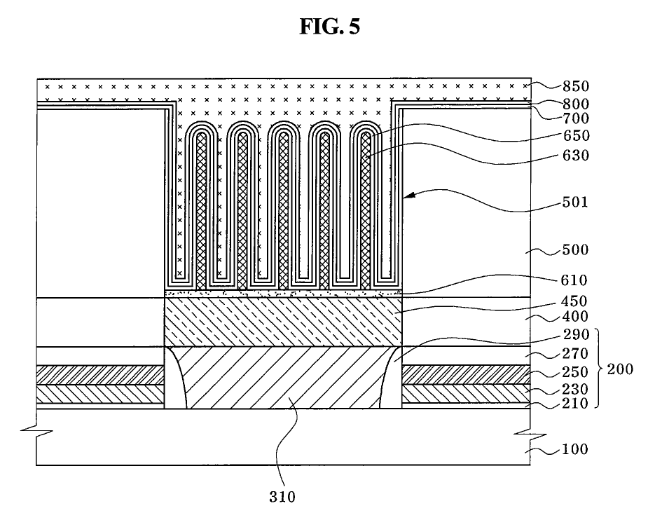

Referring to FIG. 5, an upper electrode 800 is formed on the dielectric layer 700 to complete a capacitor. The upper electrode 800 may be formed by an ALD process to include a metal layer, such as a titanium nitride layer. Alternatively, the upper electrode 800 may be formed of a tungsten nitride (WN), tantalum nitride (TaN), platinum (Pt), ruthenium (Ru) layer, or the like. Meanwhile, a capping electrode layer 850 including a poly-silicon layer may be additionally provided on the upper electrode 800.

As is apparent from the above description, according to the present invention, carbon nanotubes are preferably oriented orthogonal to a semiconductor substrate so as to increase an effective surface area of a dielectric layer. This has the effect of increasing the capacitance of a capacitor.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for forming capacitors of a memory device, the method comprising:
forming a mold layer over a semiconductor substrate, the mold layer having holes formed therein;
forming a catalytic metal layer proximate to a bottom boundary of each hole;
growing [carbon nanotubes is synthesized to grow from the surface of the catalytic layer] carbon nanotubes over the catalytic metal layer;
depositing a dielectric layer over the carbon nanotubes; and
forming upper electrodes over the dielectric layer to form capacitors.

2. The method according to claim 1, wherein the carbon nanotubes are grown substantially orthogonal to the catalytic metal layer.

3. The method according to claim 1, further comprising forming a conductive lower electrode layer over the bottom boundary and sidewall of each hole, directly on the catalytic metal layer and over the carbon nanotubes.

4. The method according to claim 3, further comprising:
forming an insulating layer over the semiconductor substrate to cover the transistors; and
forming connection contacts extending below the insulating layer to electrically connect the semiconductor substrate to the lower electrode layer.

5. The method according to claim 1, wherein the catalytic metal layer comprises a nickel (Ni) layer, an iron (Fe) layer, or both.

6. The method according to claim 1, wherein the catalytic metal layer comprises an iron-nickel binary-system alloy layer, an iron-nickel-cobalt ternary-system alloy layer, an iron-nickel-cobalt-titanium quarternary-system alloy layer, an iron-nickel-titanium ternary-system alloy layer, or a combination thereof.

7. The method according to claim 1, wherein the carbon nanotubes are grown by a catalytic reaction of a reaction gas with the catalytic metal layer, the reaction gas including hydrocarbon gas comprising acetylene gas (C₂H₄), methane gas (CH₄), or both.

8. The method according to claim 1, wherein the carbon nanotubes are grown by a catalytic reaction of a reaction gas with the catalytic metal layer, wherein the reaction gas includes ammonia gas (NH₃).

9. The method according to claim 7, wherein the reaction gas further includes inert gas serving as a carrier gas.

10. The method according to claim 1, wherein the dielectric layer comprises an aluminum oxide layer, a hafnium oxide layer, a zirconium oxide layer, or a combination thereof, deposited by an atomic layer deposition process.

11. The method according to claim 1, wherein depositing the dielectric layer comprises:
depositing a zirconium oxide layer, an aluminum oxide layer, and a zirconium oxide layer at a first temperature within the same process chamber by an atomic layer deposition process to form a composite layer; and
performing a heat treatment for the composite layer at a second temperature higher than the first temperature to enhance crystallization of the composite layer.

12. A capacitor of a memory device having transistors, the capacitor comprising:
a catalytic metal layer formed on a semiconductor substrate;
a plurality of carbon nanotubes grown over the catalytic metal layer, wherein the carbon nanotubes are substantially orthogonal to the catalytic metal layer;
a dielectric layer formed over the carbon nanotubes; and
an upper electrode formed over the dielectric layer.

13. The capacitor according to claim 12, wherein the carbon nanotubes are grown directly on the catalytic metal layer, the capacitor further comprising:
a mold layer formed on the semiconductor substrate, the mold layer defining at least one hole; and
a lower electrode layer formed proximate to a bottom boundary and sidewall of each hole and over the carbon nanotubes.

14. The capacitor according to claim 12, further comprising a lower electrode layer forming a cylindrical sidewall surrounding the periphery of the carbon nanotubes, and covering the carbon nanotubes and the catalytic metal layer.

15. The capacitor according to claim 12, further comprising:
an insulating layer formed over the semiconductor substrate to cover the transistors; and
a connection contact penetrating through the insulating layer to electrically connect the semiconductor substrate to the lower electrode layer.

16. The capacitor according to claim 12, wherein the catalytic metal layer comprises a nickel (Ni) layer, an iron (Fe) layer, or both.

17. The capacitor according to claim 12, wherein the catalytic metal layer comprises an iron-nickel binary-system alloy layer, an iron-nickel-cobalt ternary-system alloy layer, an iron-nickel-cobalt-titanium quarternary-system alloy layer, an iron-nickel-titanium ternary-system alloy layer, or both.

18. The capacitor according to claim 12, wherein the dielectric layer comprises an aluminum oxide layer, a hafnium oxide layer, a zirconium oxide layer, or a combination thereof, the dielectric layer being deposited by an atomic layer deposition process.

19. The capacitor according to claim 12, wherein the dielectric layer comprises a composite layer comprising a zirconium oxide layer, an aluminum oxide layer, and a zirconium oxide layer, which are deposited by an atomic layer deposition process.
